(19) United States
(12) Patent Application Publication
(10) Pub. No.: US 2025/0378869 A1
(43) Pub. Date: Dec. 11, 2025

(54) SEMICONDUCTOR DEVICE HAVING COMMAND SHIFTER CIRCUIT

(71) Applicant: Micron Technology, Inc., Boise, ID (US)

(72) Inventor: Yukimi Morimoto, Sagamihara (JP)

(73) Assignee: Micron Technology, Inc., Boise, ID (US)

(21) Appl. No.: 19/216,268

(22) Filed: May 22, 2025

Related U.S. Application Data
(60) Provisional application No. 63/656,240, filed on Jun. 5, 2024.

(51) Int. Cl. G11C 11/4076

(52) U.S. Cl. CPC G11C 11/4076

(57) ABSTRACT

An example apparatus includes a command shifter configured to shift a first command responsive to a first clock signal to generate a second command, a first additional path coupled to the first command shifter and configured to generate a third command responsive to the first clock signal, a second additional path coupled to the first command shifter and configured to generate a fourth command responsive to a second clock signal having different phase from the first clock signal, and a first gate circuit coupled to the first and second additional paths and configured to generate a fifth command based on the third command and the fourth command.

### CROSS-REFERENCE TO RELATED APPLICATIONS

This application claims the filing benefit of U.S. Provisional Application No. 63/656,240, filed Jun. 5, 2024. This application is incorporated by reference herein in its entirety and for all purposes.

### BACKGROUND

In recent years, the frequency of clock signals used in a semiconductor device such as a DRAM has been increasing significantly. In a DDR5 DRAM, an operation margin at the time of using a high-speed clock signal is secured by, for example, performing latency counting of commands in synchronization with a divided clock signal generated by dividing an external clock signal. When latency counting of commands is performed using a divided clock signal, its latency counting pitch becomes equivalent to two clock cycles of the external clock signal, so that there arises an issue with handling a case where the number of times of counting is an odd number.

### BRIEF DESCRIPTION OF THE DRAWINGS

FIG. 1 is a block diagram showing a configuration of a semiconductor device according to an embodiment of the present disclosure;

FIG. 2 is a waveform diagram showing relations between external clock signals and divided clock signals;

FIG. 3 is a block diagram showing a configuration of a QED shifter;

FIG. 4A and FIG. 4B are circuit diagrams of a non-swap path and a swap path;

FIG. 5 shows a generating circuit of control signals controlling non-swap paths and swap paths;

FIG. 6 is a truth table for explaining relations among various control signals; and

FIG. 7A to FIG. 7D are waveform diagrams for explaining operations of a non-swap path and a swap path.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessarily mutually exclusive, as some disclosed embodiments can be combined with one or more other disclosed embodiments to form new embodiments.

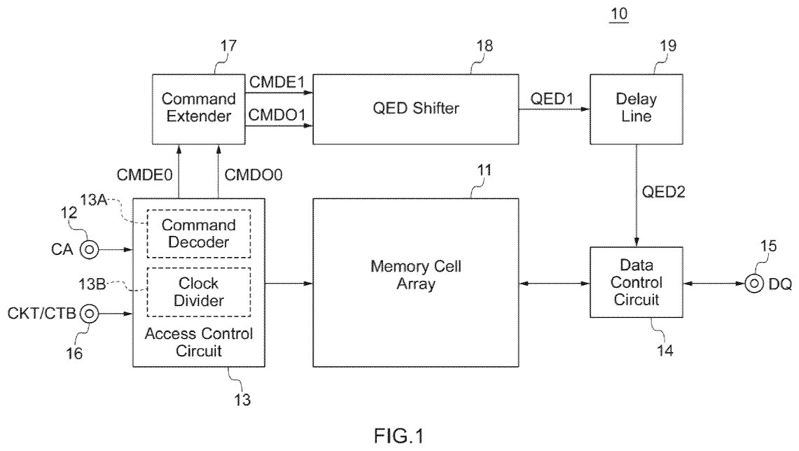

FIG. 1 is a block diagram showing a configuration of a semiconductor device 10 according to an embodiment of the present disclosure. The semiconductor device 10 shown in FIG. 1 is a DDR5 DRAM, for example, and includes a memory cell array 11. When access is made to the memory cell array 11, a command address signal CA is input from outside to a command address terminal 12. The command address signal CA is supplied to an access control circuit 13. The access control circuit 13 includes a command decoder 13A and a clock divider 13B. When an external command included in the command address signal CA indicates a read operation, the access control circuit 13 makes read-access to a memory cell included in the memory cell array 11 based on an address included in the command address signal CA. Read data DQ read from the accessed memory cell is output from a data I/O terminal 15 to outside via a data control circuit 14. When the external command included in the command address signal CA indicates a write operation, write data DQ input from outside to the data I/O terminal 15 is transferred to the memory cell array 11 via the data control circuit 14. The write data DQ having been transferred to the memory cell array 11 is written in the memory cell included in the memory cell array 11 based on the address included in the command address signal CA.

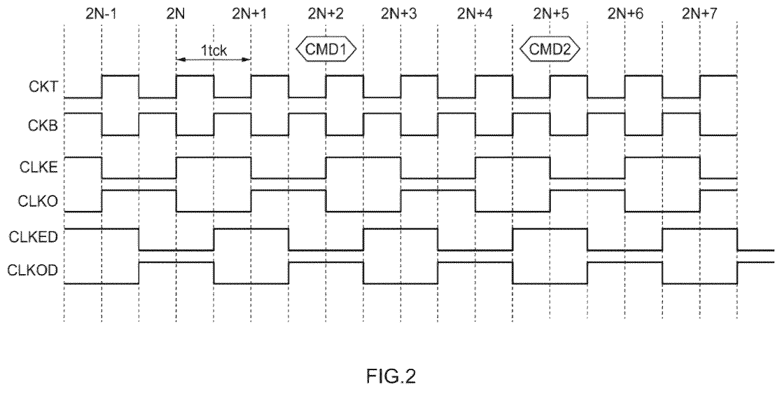

The operation of the access control circuit 13 is performed in synchronization with complementary external clock signals CKT and CKB that are input to a clock terminal 16. The complementary external clock signals CKT and CKB are supplied to the clock driver 13B. The clock divider 13B generates divided clock signals CLKE and CLKO shown in FIG. 2 by dividing the complementary external clock signals CKT and CKB. The divided clock signal CLKE rises in synchronization with even-numbered active edges of the external clock signals CKT and CKB and falls in synchronization with odd-numbered active edges of the external clock signals CKT and CKB. The divided clock signal CLKO rises in synchronization with odd-numbered active edges of the external clock signals CKT and CKB and falls in synchronization with even-numbered active edges of the external clock signals CKT and CKB. That is, the divided clock signals CLKE and CLKO have twice the frequency of the external clock signals CKT and CKB. The clock divider 13B further generates delayed divided clock signals CLKED and CLKOD. The divided clock signal CLKED is generated by, for example, delaying the divided clock signal CLKE and the rising edge thereof is positioned between the rising edge of the divided clock signal CLKE and the rising edge of the divided clock signal CLKO. The divided clock signal CLKOD is generated by, for example, delaying the divided clock signal CLKO and the rising edge thereof is positioned between the rising edge of the divided clock signal CLKO and the rising edge of the divided clock signal CLKE. In the example shown in FIG. 2, the delayed divided clock signals CLKED and CLKOD are delayed by 0.5 tck with respect to the divided clock signals CLKE and CLKO, respectively.

When the external command included in the command address signal CA indicates a read operation, a write operation, a Read non-target operation, or a Write non-target operation, the command decoder 13A included in the access control circuit 13 activates a respective internal command CMDE0 or a respective internal command CMDO0. The internal command CMDE0 is activated when the external command is input in synchronization with even-numbered active edges of the external clock signals CKT and CKB. For example, when a command CMD1 shown in FIG. 2 is input at a timing 2N+2, an internal command CMDE0 is activated. The internal command CMDO0 is activated when the external command is input in synchronization with odd-numbered active edges of the external clock signals CKT and CKB. For example, when a command CMD2 shown in FIG. 2 is input at a timing 2N+5, the internal command CMDO0 is activated.

The internal commands CMDE0 and CMDO0 are respectively converted into internal commands CMDE1 and CMDO1 by a command extender 17 that adjusts command widths. The internal commands CMDE1 and CMDO1 are supplied to a QED shifter 18. The QED shifter 18 counts a predetermined latency after the internal commands CMDE1 and CMDO1 are input therein, and then generates an internal command QED1. The internal command QED1 is converted into an internal command QED2 by a delay line 19 that causes a predetermined delay. The internal command QED2 is input to the data control circuit 14. The data control circuit 14 outputs the read data DQ and latches the write data DQ in synchronization with the internal command QED2.

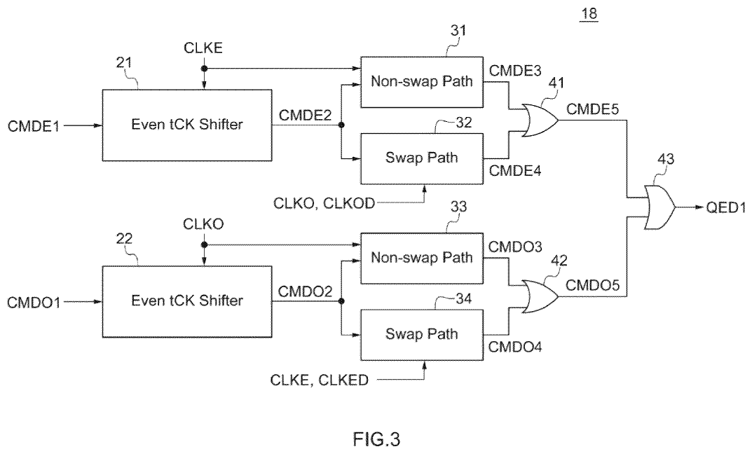

FIG. 3 is a block diagram showing a configuration of the QED shifter 18. As shown in FIG. 3, the QED shifter 18 includes a command shifter 21 that performs a shifting operation on the internal command CMDE1 in synchronization with the divided clock signal CLKE and a command shifter 22 that performs a shifting operation on the internal command CMDO1 in synchronization with the divided clock signal CLKO. With this configuration, an internal command CMDE2 is delayed only by even-numbered clock cycles with respect to the internal command CMDE1 and an internal command CMDO2 is delayed only by even-numbered clock cycles with respect to the internal command CMDO1. The number of times of shifting by the command shifters 21 and 22 are determined by a mode register setting operation or an initializing operation of the delay line 19. The internal command CMDE2 output from the command shifter 21 is commonly supplied to a non-swap path 31 and a swap path 32. The internal command CMDO2 output from the command shifter 22 is commonly supplied to a non-swap path 33 and a swap path 34.

The non-swap path 31 performs a shifting operation on the internal command CMDE2 in synchronization with the divided clock signal CLKE to generate an internal command CMDE3. With this process, the internal command CMDE3 is delayed only by even-numbered clock cycles with respect to the internal command CMDE2. The swap path 32 performs a shifting operation on the internal command CMDE2 in synchronization with the divided clock signals CLKO and CLKOD to generate an internal command CMDE4. With this process, the internal command CMDE4 is delayed only by odd-numbered clock cycles with respect to the internal command CMDE2. The non-swap path 33 performs a shifting operation on the internal command CMDO2 in synchronization with the divided clock signal CLKO to generate an internal command CMDO3. With this process, the internal command CMDO3 is delayed only by even-numbered clock cycles with respect to the internal command CMDO2. The swap path 34 performs a shifting operation on the internal command CMDO2 in synchronization with the divided clock signals CLKE and CLKED to generate an internal command CMDO4. With this process, the internal command CMDO4 is delayed only by odd-numbered clock cycles with respect to the internal command CMDO2.

The internal commands CMDE3 and CMDE4 are synthesized with each other by an OR gate circuit 41. The internal commands CMDO3 and CMDO4 are synthesized with each other by an OR gate circuit 42. An internal command CMDE5 output from the OR gate circuit 41 and an internal command CMDO5 output from the OR gate circuit 42 are synthesized with each other by an OR gate circuit 43. With this process, the internal command QED1 is generated.

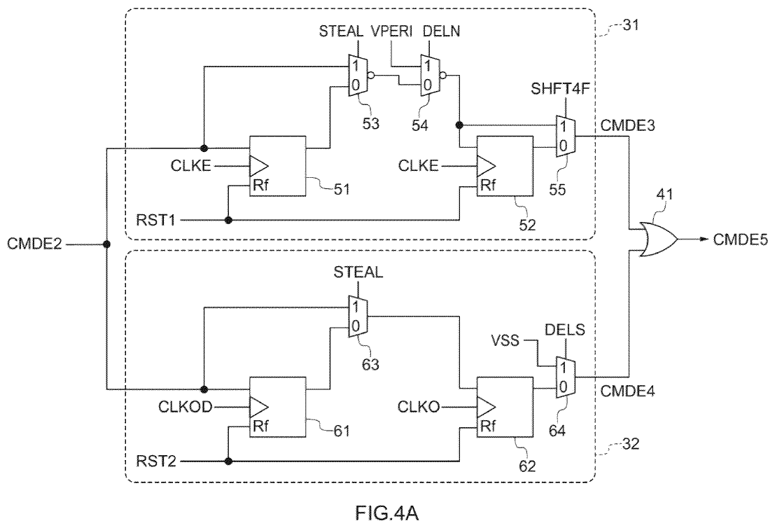

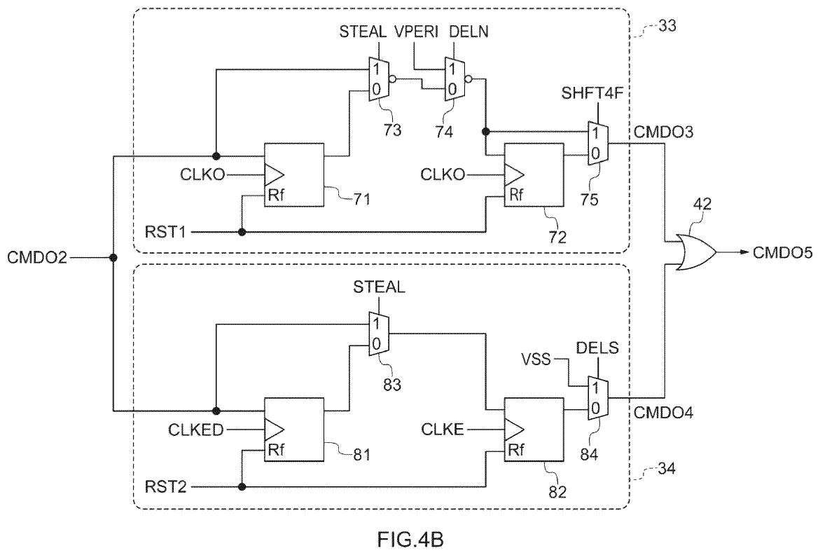

FIG. 4A is a circuit diagram of the non-swap path 31 and the swap path 32. The non-swap path 31 is a circuit that causes a two-clock cycle delay or a four-clock cycle delay to the internal command CMDE2 and includes latch circuits 51 and 52 each of which performs a latch operation in synchronization with the divided clock signal CLKE and multiplexers 53 to 55. The internal command CMDE2 is supplied to an input node of the latch circuit 51. Output of the latch circuit 51 is supplied to an input node of the latch circuit 52 via the multiplexers 53 and 54. Output of the latch circuit 52 is supplied to one input node of the OR gate circuit 41 via the multiplexer 55. The multiplexers 53 to 55 are respectively controlled with control signals STEAL, DELN, and SHFT4F. The latch circuits 51 and 52 are both reset with a reset signal RST1. The swap path 32 is a circuit that causes a three-clock cycle delay to the internal command CMDE2 and includes a latch circuit 61 that performs a latch operation in synchronization with the delayed divided clock signal CLKOD, a latch circuit 62 that performs a latch operation in synchronization with the divided clock signal CLKO, and multiplexers 63 and 64. The internal command CMDE2 is supplied to an input node of the latch circuit 61. Output of the latch circuit 61 is supplied to an input node of the latch circuit 62 via the multiplexer 63. Output of the latch circuit 62 is supplied to the other input node of the OR gate circuit 41 via the multiplexer 64. The multiplexers 63 and 64 are respectively controlled with the control signal STEAL and a control signal DELS. The latch circuits 61 and 62 are both reset with a reset signal RST2.

FIG. 4B is a circuit diagram of the non-swap path 33 and the swap path 34. The non-swap path 33 is a circuit that causes a two-clock cycle delay or a four-clock cycle delay to the internal command CMDO2 and includes latch circuits 71 and 72 each of which performs a latch operation in synchronization with the divided clock signal CLKO and multiplexers 73 to 75. The internal command CMDO2 is supplied to an input node of the latch circuit 71. Output of the latch circuit 71 is supplied to an input node of the latch circuit 72 via the multiplexers 73 and 74. Output of the latch circuit 72 is supplied to one input node of the OR gate circuit 42 via the multiplexer 75. The multiplexers 73 to 75 are respectively controlled with control signals STEAL, DELN, and SHFT4F. The latch circuits 71 and 72 are both reset with the reset signal RST1. The swap path 34 is a circuit that causes a three-clock cycle delay to the internal command CMDO2 and includes a latch circuit 81 that performs a latch operation in synchronization with the delayed divided clock signal CLKED, a latch circuit 82 that performs a latch operation in synchronization with the divided clock signal CLKE, and multiplexers 83 and 84. The internal command CMDO2 is supplied to an input node of the latch circuit 81. Output of the latch circuit 81 is supplied to an input node of the latch circuit 82 via the multiplexer 83. Output of the latch circuit 82 is supplied to the other input node of the OR gate circuit 42 via the multiplexer 84. The multiplexers 83 and 84 are respectively controlled with the control signals STEAL and DELS. The latch circuits 81 and 82 are both reset with the reset signal RST2.

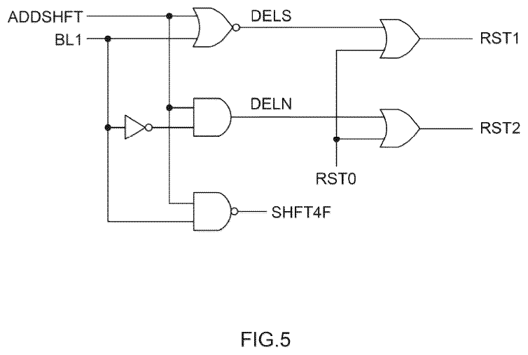

FIG. 5 shows a generating circuit of control signals controlling the non-swap paths 31 and 33 and the swap paths 32 and 34. The circuit shown in FIG. 5 generates the control signals DELS, DELN, SHFT4F, RST1, and RST2 based on control signals ADDSHFT, BL1, and RST0. These control signals are supplied to the non-swap paths 31 and 33 and the swap paths 32 and 34 shown in FIGS. 4A and 4B.

Here, the control signal ADDSHFT is activated when it is necessary to cause an odd-numbered clock cycle delay to the internal command CMDE2 or CMDO2. The control signal BL1 is activated when it is necessary to extend the pulse width of the internal command CMDE2 or CMDO2 by only one clock cycle. The control signal STEAL shown in FIGS. 4A and 4B is normally at a low level (0) and becomes a high level (1) when the shift amount taken by the swap paths 32 and 34 is set to be one clock cycle. That is, when the control signal STEAL is at a high level, the latch circuit 61 included in the swap path 32 is bypassed and the latch circuit 81 included in the swap path 34 is also bypassed. Further, when the control signal STEAL is 1 and the control signal DELN is 0 or the control signal SHFT4F is 1 and the control signal DELN is 0, the shift amount taken by the non-swap paths 31 and 33 becomes two clock cycles. That is, when the control signal STEAL or SHFT4F is at a high level and the control signal DELN is at a low level, the latch circuit 51 or 52 included in the non-swap path 31 is bypassed and the latch circuit 71 or 72 included in the non-swap path 33 is also bypassed.

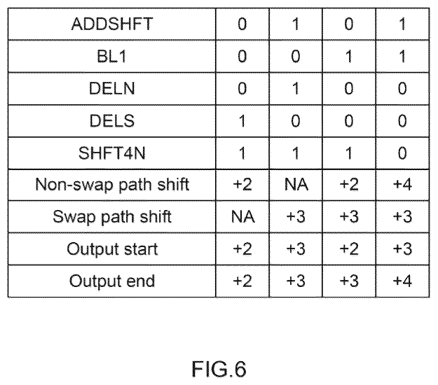

FIG. 6 is a truth table for explaining relations among the control signals ADDSHFT and BL1 and the control signals DELN, DELS, and SHFT4N, and FIG. 6 represents a state where the control signal STEAL is 0.

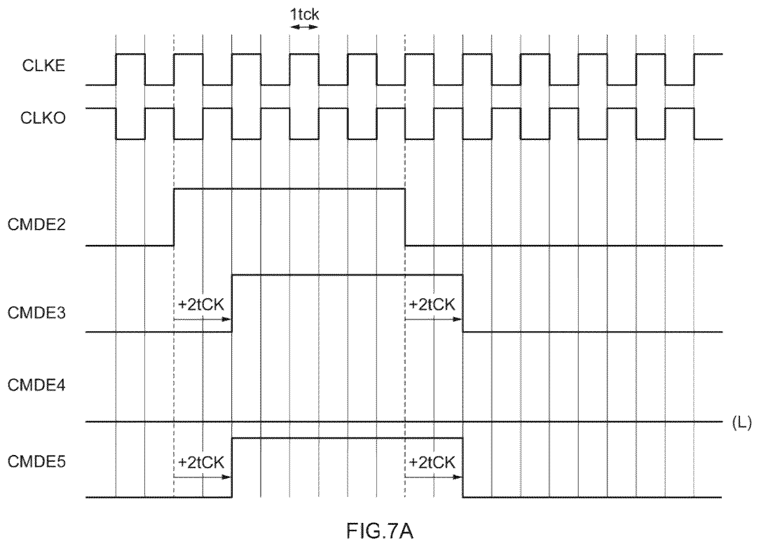

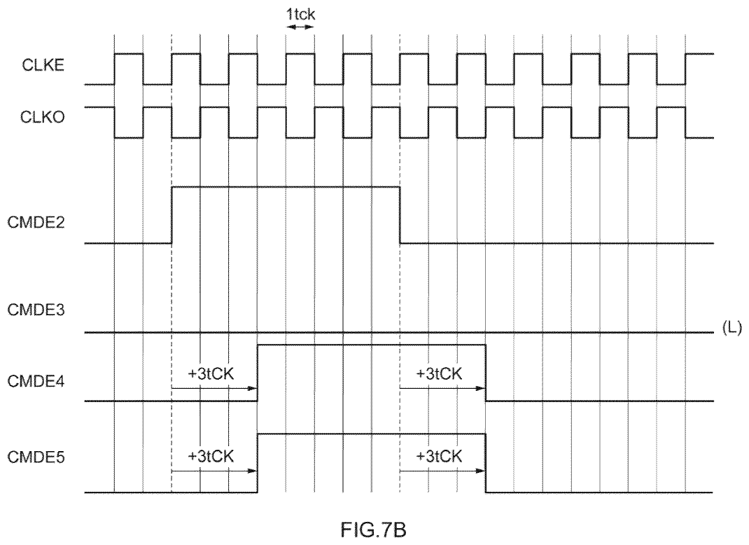

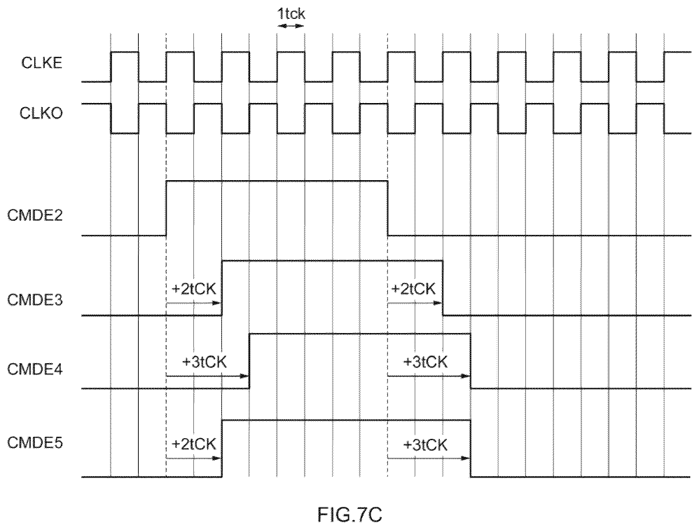

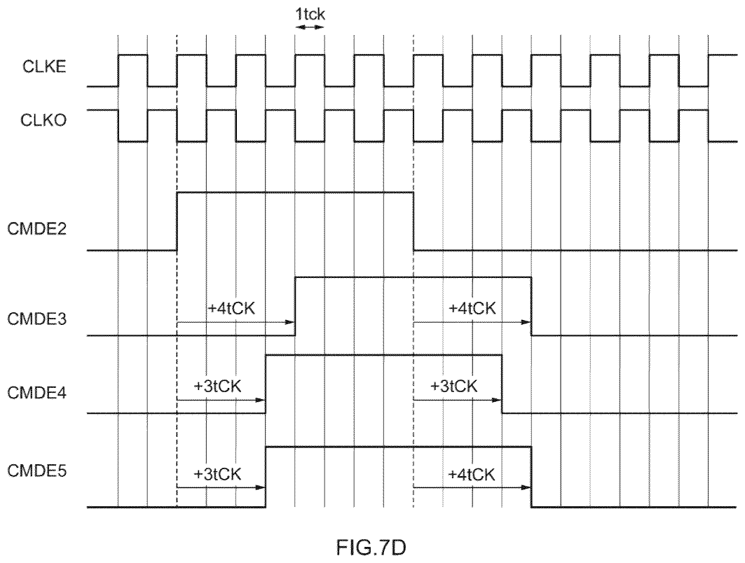

First, in the circuit shown in FIG. 5, when the control signal ADDSHFT is 0 and the control signal BL1 is 0, the control signal DELN is 0, the control signal DELS is 1, and the control signal SHFT4F is 1. Accordingly, the waveforms of the internal commands CMDE2 to CMDE5 are as shown in FIG. 7A, for example. That is, since the latch circuit 52 included in the non-swap path 31 is bypassed in response to the control signal SHFT4F being 1, the non-swap path 31 delays the internal command CMDE2 by two clock cycles using a one-stage latch circuit 51 to generate the internal command CMDE3. Further, since the multiplexer 64 selects to be a low level (=VSS) in response to the control signal DELS being 1, the swap path 32 is disabled and the internal command CMDE4 is fixed to a low level. As a result, as for the internal command CMDE5 output from the OR gate circuit 41, the rising edge and falling edge thereof are delayed by two clock cycles with respect to the internal command CMDE2. That is, the internal command CMDE5 has a pulse width same as that of the internal command CMDE2 and becomes a signal having the internal command CMDE2 delayed by two clock cycles.

In the circuit shown in FIG. 5, when the control signal ADDSHFT is 1 and the control signal BL1 is 0, the control signal DELN is 1, the control signal DELS is 0, and the control signal SHFT4F is 1. Accordingly, the waveforms of the internal commands CMDE2 to CMDE5 are as shown in FIG. 7B, for example. That is, since the multiplexer 54 selects to be a high level (=VPERI) in response to the control signal DELN being 1, the non-swap path 31 is disabled and the internal command CMDE3 is fixed to a low level. Further, the swap path 32 has a state where two-stage latch circuits 61 and 62 are coupled to each other in series. Here, since the last-stage latch circuit 62 performs a latch operation in synchronization with the divided clock signal CLKO, the swap path 32 delays the internal command CMDE2 by three clock cycles to generate the internal command CMDE4. As a result, as for the internal command CMDE5 output from the OR gate circuit 41, the rising edge and falling edge thereof are delayed by three clock cycles with respect to the internal command CMDE2. That is, the internal command CMDE5 has a pulse width same as that of the internal command CMDE2 and becomes a signal having the internal command CMDE2 delayed by three clock cycles. Further, since the first-stage latch circuit 61 performs a latch operation in synchronization with the delayed divided clock signal CLKOD, latch margins at the first-stage latch circuits 61 and 62 are also increased. For example, the latch margins at the latch circuits 61 and 62 are both 1.5 tCK.

In the circuit shown in FIG. 5, when the control signal ADDSHFT is 0 and the control signal BL1 is 1, the control signal DELN is 0, the control signal DELS is 0, and the control signal SHFT4F is 1. Accordingly, the waveforms of the internal commands CMDE2 to CMDE5 are as shown in FIG. 7C, for example. That is, since the latch circuit 52 included in the non-swap path 31 is bypassed in response to the control signal SHFT4F being 1, the non-swap path 31 delays the internal command CMDE2 by two clock cycles using the one-stage latch circuit 51 to generate the internal command CMDE3. Further, the swap path 32 has a state where the two-stage latch circuits 61 and 62 are coupled to each other in series. As a result, as for the internal command CMDE5 output from the OR gate circuit 41, the rising edge thereof is delayed by two clock cycles with respect to the internal command CMDE2 and the falling edge thereof is delayed by three clock cycles with respect to the internal command CMDE2. That is, the internal command CMDE5 has a pulse width extended by one clock cycle as compared to that of the internal command CMDE2 and becomes a signal having the internal command CMDE2 delayed by two clock cycles.

In the circuit shown in FIG. 5, when the control signal ADDSHFT is 1 and the control signal BL1 is 1, the control signal DELN is 0, the control signal DELS is 0, and the control signal SHFT4F is 0. Accordingly, the waveforms of the internal commands CMDE2 to CMDE5 are as shown in FIG. 7D, for example. That is, since the non-swap path 31 has a state where two-stage latch circuits 51 and 52 are coupled to each other in series, the non-swap path 31 delays the internal command CMDE2 by four clock cycles using the two-stage latch circuits 51 and 52 to generate the internal command CMDE3. Further, the swap path 32 has a state where the two-stage latch circuits 61 and 62 are coupled to each other in series. As a result, as for the internal command CMDE5 output from the OR gate circuit 41, the rising edge thereof is delayed by three clock cycles with respect to the internal command CMDE2 and the falling edge thereof is delayed by four clock cycles with respect to the internal command CMDE2. That is, the internal command CMDE5 has a pulse width extended by one clock cycle as compared to that of the internal command CMDE2 and becomes a signal having the internal command CMDE2 delayed by three clock cycles.

The operations of the non-swap path 31 and the swap path 32 described above with reference to FIGS. 7A to 7D are also applied to the non-swap path 33 and the swap path 34. Further, the internal command CMDE5 generated by passing through the non-swap path 31 and the swap path 32 and the internal command CMDO5 generated by passing through the non-swap path 33 and the swap path 34 are synthesized with each other by the OR gate circuit 43 shown in FIG. 3, thereby generating the internal command QED1.

As described above, in the semiconductor device according to the present disclosure, the non-swap path 31 causing an even-numbered clock cycle delay to the internal command CMDE2 and the swap path 32 causing an odd-numbered clock cycle delay to the internal command CMDE2 are coupled to each other in parallel and the internal command CMDE3 output from the non-swap path 31 and the internal command CMDE4 output from the swap path 32 are synthesized with each other, so that it is possible to cause an odd-numbered clock cycle delay to the internal command CMDE1 while securing a sufficient operation margin. Similarly, the non-swap path 33 causing an even-numbered clock cycle delay to the internal command CMDO2 and the swap path 34 causing an odd-numbered clock cycle delay to the internal command CMDO2 are coupled to each other in parallel and the internal command CMDO3 output from the non-swap path 33 and the internal command CMDO4 output from the swap path 34 are synthesized with each other, so that it is possible to cause an odd-numbered clock cycle delay to the internal command CMDO1 while securing a sufficient operation margin.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
a first command shifter configured to shift a first command responsive to a first clock signal to generate a second command;
a first additional path coupled to the first command shifter and configured to generate a third command responsive to the first clock signal;
a second additional path coupled to the first command shifter and configured to generate a fourth command responsive to a second clock signal having different phase from the first clock signal; and
a first gate circuit coupled to the first and second additional paths and configured to generate a fifth command based on the third command and the fourth command.

2. The apparatus of claim 1, wherein the second clock signal has an opposite phase to the first clock signal.

3. The apparatus of claim 1,
wherein the first additional path includes a first latch circuit configured to output the third command in synchronization with the first clock signal, and
wherein the second additional path includes a second latch circuit configured to output the fourth command in synchronization with the second clock signal.

4. The apparatus of claim 3,
wherein the first additional path includes a first input node coupled to the first command shifter, a first output node coupled to the first gate circuit, and a plurality of latch circuits including the first latch circuit coupled in series between the first input node and the first output node, and
wherein each of the plurality of latch circuits of the first additional path is configured to perform a latch operation in synchronization with the first clock signal.

5. The apparatus of claim 4, wherein one or ones of the plurality of latch circuits of the first additional path is configured to be bypassed based on a first control signal.

6. The apparatus of claim 5, wherein the second additional path includes a second input node coupled to the first command shifter, a second output node coupled to the first gate circuit, and a plurality of latch circuits including the second latch circuit coupled in series between the second input node and the second output node.

7. The apparatus of claim 6, wherein one or ones of the plurality of latch circuits of the second additional path is configured to be bypassed based on a second control signal.

8. The apparatus of claim 7,
wherein the plurality of latch circuits of the second additional path include a third latch circuit configured to perform a latch operation in synchronization with a third clock signal, and
wherein an active edge of the third clock signal appears between an active edge of the first clock signal and an active edge of the second clock signal.

9. The apparatus of claim 8, wherein the third latch circuit has the second input node such that the second command is latched in the third latch circuit.

10. The apparatus of claim 8, wherein the third clock signal is generated by delaying the second clock signal.

11. The apparatus of claim 2, further comprising:
a second command shifter configured to shift a sixth command responsive to the second clock signal to generate a seventh command;
a third additional path coupled to the second command shifter and configured to generate an eighth command responsive to the second clock signal;
a fourth additional path coupled to the second command shifter and configured to generate a ninth command responsive to the first clock signal;
a second gate circuit coupled to the third and fourth additional paths and configured to generate a tenth command based on the eighth command and the ninth command; and
a third gate circuit coupled to the first and second gate circuits and configured to generate an eleventh command based on the fifth command and the tenth command.

12. The apparatus of claim 11, further comprising:
an external terminal electrode configured to receive an external command; and
a command decoder configured to decode the external command responsive to a third clock signal having twice a frequency of the first and second clock signals,
wherein the command decoder is configured to:
generate the first command when the external command is received in synchronization with an even-numbered edge of the third clock signal; and
generate the sixth command when the external command is received in synchronization with an odd-numbered edge of the third clock signal.

13. An apparatus comprising:
a clock divider configured to divide an original clock signal to generate first and second divided clock signals having opposite phases to each other;
a first command shifter configured to shift a first command responsive to the first divided clock signal to generate a second command, wherein a delay amount of the second command from the first command is even-numbered clock cycles of the original clock signal;
a first additional path coupled to the first command shifter and configured to generate a third command responsive to the first divided clock signal, wherein a delay amount of the third command from the second command is even-numbered clock cycles of the original clock signal;
a second additional path coupled to the first command shifter and configured to generate a fourth command responsive to the second divided clock signal, wherein a delay amount of the fourth command from the second command is odd-numbered clock cycles of the original clock signal; and
a first gate circuit coupled to the first and second additional paths and configured to generate a fifth command based on the third command and the fourth command.

14. The apparatus of claim 13,
wherein the first and second additional paths are configured to be controlled by a control signal, and
wherein, when the control signal indicates a first state, the second additional path is configured to be inactivated such that a delay amount of the fifth command from the second command is even-numbered clock cycles of the original clock signal.

15. The apparatus of claim 14, wherein, when the control signal indicates a second state, the first additional path is configured to be inactivated such that a delay amount of the fifth command from the second command is odd-numbered clock cycles of the original clock signal.

16. The apparatus of claim 15, wherein, when the control signal indicates a third state, the first additional path is configured to generate the third command by adding a first amount of clock cycles of the original clock signal to the second command, and the second additional path is configured to generate the fourth command by adding a second amount of clock cycles of the original clock signal to the second command.

17. The apparatus of claim 16, wherein, when the control signal indicates the third state, a delay amount of a start edge of the fifth command from a start edge of the second command is even-numbered clock cycles of the original clock signal, and a delay amount of an end edge of the fifth command from an end edge of the second command is odd-numbered clock cycles of the original clock signal.

18. The apparatus of claim 17, wherein, when the control signal indicates a fourth state, the first additional path is configured to generate the third command by adding a third amount of clock cycles of the original clock signal to the second command, and the second additional path is configured to generate the fourth command by adding the second amount of clock cycles of the original clock signal to the second command.

19. The apparatus of claim 18, wherein, when the control signal indicates the fourth state, a delay amount of the start edge of the fifth command from the start edge of the second command is odd-numbered clock cycles of the original clock signal, and a delay amount of the end edge of the fifth command from the end edge of the second command is even-numbered clock cycles of the original clock signal.

20. The apparatus of claim 13, further comprising:
a second command shifter configured to shift a sixth command responsive to the second divided clock signal to generate a seventh command, wherein a delay amount of the seventh command from the sixth command is even-numbered clock cycles of the original clock signal;
a third additional path coupled to the second command shifter and configured to generate an eighth command responsive to the second divided clock signal, wherein a delay amount of the eighth command from the seventh command is even-numbered clock cycles of the original clock signal;
a fourth additional path coupled to the second command shifter and configured to generate a ninth command responsive to the first divided clock signal, wherein a delay amount of the ninth command from the seventh command is odd-numbered clock cycles of the original clock signal;
a second gate circuit coupled to the third and fourth additional paths and configured to generate a tenth command based on the eighth command and the ninth command; and
a third gate circuit coupled to the first and second gate circuits and configured to generate an eleventh command based on the fifth command and the tenth command.

21. An apparatus comprising:
a first signal path including a plurality of latch circuit coupled in series between an input node and a first signal node;
a second signal path including a plurality of latch circuit coupled in series between the input node and a second signal node; and
a gate circuit configured to synthesize a first signal appearing at the first signal node and a second signal appearing at the first signal node to generate an output signal,
wherein the plurality of latch circuit of the first signal path include a first latch circuit configured to perform a latch operation in synchronization with a first clock signal,
wherein the plurality of latch circuit of the second signal path include a second latch circuit configured to perform a latch operation in synchronization with a second clock signal and a third latch circuit configured to perform a latch operation in synchronization with a third clock signal,
wherein the third latch circuit is coupled between the input node and the second latch circuit, and
wherein a phase of the third clock signal is between a phase of the first clock signal and a phase of the second clock signal.
